(19) United States
(12) Patent Application Publication
(10) Pub. No.: US 2024/0072226 A1
(43) Pub. Date: Feb. 29, 2024

(54) SEMICONDUCTOR DEVICE AND METHOD OF MANUFACTURING THE SAME

(71) Applicant: ams-OSRAM International GmbH, Regensburg (DE)

(72) Inventor: Thomas Schwarz, Regensburg (DE)

(21) Appl. No.: 18/258,311

(22) PCT Filed: Dec. 21, 2021
(86) PCT No.: PCT/EP2021/087068

§ 371 Date: Jun. 19, 2023

(30) Foreign Application Priority Data
Dec. 22, 2020 (DE) 10 2020 134 702.2

(51) Int. Cl. H01L 33/62; H01L 25/075; H01L 33/46; H01L 33/54

(52) U.S. Cl. CPC H01L 33/62; H01L 25/0753; H01L 33/46; H01L 33/54; H01L 2933/005; H01L 2933/0066; H01L 2933/0091

(57) ABSTRACT

In an embodiment a semiconductor device includes a semiconductor component having a first electrical contact surface on a top side and a second electrical contact surface opposite the top side, a filler material enclosing the semiconductor component as seen in a circumferential direction, the filler material covering at least a partial region of a side surface of the component connecting the top side and the bottom side, at least one conductor track arranged on a top side of the filler material, the at least one conductor track being electrically connected to the first electrical contact surface and a first connection point and a second connection point arranged adjacent to a bottom side of the filler material opposite the top side of the filler material, the first connection point being electrically connected to the at least one conductor track via a through-plating through the filler material and the second connection point being electrically connected to the second electrical contact surface.

### CROSS-REFERENCE TO RELATED APPLICATIONS

This patent application is a national phase filing under section 371 of PCT/EP2021/087068, filed Dec. 21, 2021, which claims the priority of German patent application 102020134702.2, filed Dec. 22, 2020, each of which is incorporated herein by reference in its entirety.

### TECHNICAL FIELD

The present invention relates to a semiconductor component, in particular an optoelectronic lighting device, and to a method of manufacturing a semiconductor component, in particular an optoelectronic lighting device.

### BACKGROUND

For the fabrication of semiconductor devices, in particular flat semiconductor devices, for example, a so-called planar interconnect method can be used to provide electrical connections within the semiconductor devices. However, a production line for manufacturing such semiconductor components usually consists of several expensive manufacturing systems such as a laser direct exposure (LDI) system, a spraying system, a laminating system, a continuous developer and etching system, a sputtering system and a system for electroplating the components.

Semiconductor devices that use wire contacts, on the other hand, can be susceptible to damage to the wire contacts during handling in manufacturing or during further use of the semiconductor devices. One attempt to reduce the susceptibility to damage of the wire contacts during further use of the semiconductor components is to encapsulate the semiconductor components with, for example, silicone, but damage to the wire contacts can still occur, especially during handling in production.

In addition to these aspects, good heat dissipation is required for semiconductor components, especially optoelectronic semiconductor components such as front lights in the automotive sector or components with a high luminance (projection). Semiconductor components with a first electrical contact area on a top side of the component, a second electrical contact area on a bottom side of the component opposite the top side, and a possible conversion element on the top side of the semiconductor components are currently cooled via the bottom side of the components. However, an optimal heat dissipation of the heat generated at the top side of the semiconductor components is not always guaranteed by this.

### SUMMARY

Embodiments provide a semiconductor device, in particular an optoelectronic lighting device, as well as a method for manufacturing a semiconductor device, in particular an optoelectronic lighting device, in which at least some of the above-mentioned problematic aspects are addressed.

A semiconductor device according to embodiments of the invention, in particular an optoelectronic lighting device, comprises a semiconductor component having a first electrical contact surface on a top side of the component and a second electrical contact surface on a bottom side of the component opposite the top side. Further, the semiconductor device comprises a filler material surrounding the semiconductor device as viewed in a circumferential direction. The filler material covers at least a partial area of a side surface of the component connecting the top side and the bottom side of the component, in particular substantially the entire side surface. At least one conductor track is arranged on a top side of the filler material, which is electrically connected to the first electrical contact surface. A first and a second connection point are further arranged adjacent to an bottom side of the filler material opposite the top side of the filler material, the first connection point being electrically connected to the at least one conductor track via a through-plating through the filler material and the second connection point being electrically connected to the second electrical contact area. In particular, the through-plating is also enclosed by the filler material, viewed in a circumferential direction. The through-plating comprises a layered structure, in particular forming a corrugated structure, and/or at least one undercut to fix the filler material.

In some embodiments, the semiconductor device comprises a further contact through the filler material that electrically connects the second connection point to the second electrical contact area.

The further contact may also comprise a layered structure, in particular forming a corrugated structure, and/or at least one undercut to fix the filler material.

In some embodiments, at least one of the at least one conductive path, the first and second connection points, the through-plating, and the further contact comprises at least one printed and/or sintered layer of an electrically conductive material. In particular, the at least one printed and/or sintered layer may comprise a metal, in particular copper.

The through-plating and the further contact may each comprise a plurality of superimposed printed and/or sintered layers of an electrically conductive material. The plurality of superimposed printed and/or sintered layers can, for example, result in a corrugated structure and/or at least one undercut for the through-plating and the further contact on their side surfaces, since the superimposed layers do not, for example, terminate laterally with perfect congruence.

The through-plating and/or the further contact can be produced, for example, by means of a 3D printing and/or hardening/sintering process, so that a layer-by-layer structure, in particular forming a corrugated structure, and/or at least one undercut results. The individual layers of the through-plating and/or the further contact can have essentially the same height, or a layer of the layered structure of the through-plating and a corresponding layer of the further contact can have essentially the same thickness.

By the term undercut may be meant, for example, that a third layer of the layers of the through-plating and/or the further contact, which is located between two layers, is offset inwardly or outwardly with respect to a side surface of the layered structure in comparison with the layer above and the layer below. In other words, the side edges of two or more adjacent layers are offset from each other. In particular, the term undercut may mean that the layered structure of the through-plating and/or the further contact with only one parting line could not be demolded in the case of a cast component. The layered structure, in particular at least one undercut, allows the filler material to be fixed relative to the through-plating and/or the further contact. For this purpose, the filler material can extend into the undercut and thus be fixed with respect to the through-plating and/or the further contact.

In some embodiments, the semiconductor device comprises a semiconductor chip having at least one electrical contact area on the top side thereof. For example, the semiconductor device may comprise an integrated circuit (IC), a sensor, a detector, or an emitter. Similarly, the semiconductor device may comprise a plurality of semiconductor chips or a plurality of the aforementioned devices. In some embodiments, the semiconductor device may be formed by an optoelectronic device, in particular an optoelectronic semiconductor chip.

In some embodiments, the filler material comprises an electrically insulating material, in particular a ceramic material or a plastic. The filler material may be characterized, for example, by having electrically insulating properties and, by having high strength to provide stability to the semiconductor device. In particular, the filler material may be particularly hard. In some embodiments, the filler material exhibits load-bearing properties.

For better heat dissipation and to increase the efficiency and performance of the semiconductor device, the semiconductor component may be contacted at both its top and bottom sides. In particular, the contacting at the top side of the semiconductor component may be implemented via the at least one conductive path and the through-platings such that heat generated in the semiconductor component can be better dissipated.

In some embodiments, the at least one conductive trace electrically connected to the first electrical contact area and the through-plating is configured to be relatively wide for better heat dissipation. For example, viewed in the direction of the stacked layers of the through-plating, the at least one conductive path may have a width that is substantially the same as the width of the semiconductor component.

In some embodiments, the through-plating comprises a relatively large cross-sectional area as viewed in the direction of the stacked layers. For example, the through-plating may have a cross-sectional area, as viewed in the direction of the stacked layers, that substantially corresponds to a quarter, in particular more than a quarter, of the cross-sectional area of the semiconductor component, as viewed in the same direction.

In some embodiments, the through-plating comprises a cross-sectional area, as viewed in the direction of the stacked layers, that has a width or diameter. For example, the ratio of the width or diameter to a height of the through-plating, as viewed in the direction of the stacked layers, may range from 0.1 to 1 to 10 to 1. Better heat dissipation of heat generated in the semiconductor component can be achieved, for example, with a ratio of 10 to 1. The height of the through-platings may be, for example, between 5 and 1000 μm.

In some embodiments, the through-plating comprises a circular, a rectangular, a square, an annular, or frame-shaped cross-sectional area, as viewed in the direction of the stacked layers, and is disposed adjacent to the semiconductor component. In some embodiments, the through-plating comprises an annular or frame-shaped cross-sectional area, as viewed in the direction of the stacked layers, with the semiconductor component disposed in the center thereof. One or more, in particular two or four, spaced-apart columns may extend from the annular or frame-shaped cross-sectional area, as viewed in the direction of the superimposed layers, and may be arranged, for example, point-symmetrically or axis-symmetrically about the center of the semiconductor device.

In some embodiments, the through-platings comprise an annular or frame-shaped cross-sectional area in the region of the bottom side of the semiconductor component, viewed in the direction of the superimposed layers, in the center of which the semiconductor component is arranged. One or more, in particular two or four, spaced-apart columns extend from the annular or frame-shaped cross-sectional area, as viewed in the direction of the superimposed layers, which columns are arranged, for example, point-symmetrically or axis-symmetrically about the center of the semiconductor component. The one or more pillars of the through-plating may each be electrically connected to the first electrical contact area via a conductor track. Accordingly, one or more, in particular two or four, conductor tracks can also be arranged point-symmetrically or axis-symmetrically around the center of the semiconductor component and electrically connected to the first electrical contact area.

By means of a through-plating or conductor tracks formed in this way, for example, the heat generated in the semiconductor component can be dissipated more effectively and thus the efficiency and performance of the semiconductor device can be increased.

In some embodiments, an at least partially transparent layer is disposed on the top side of the filler material. The partially transparent layer may, for example, have light scattering or light shaping properties or may be configured to protect underlying elements or elements of the semiconductor device embedded therein from corrosion. The partially transparent layer may comprise, for example, a plastic, in particular silicone, and may form a finishing layer above the semiconductor device to improve the optical and/or mechanical properties of the semiconductor device.

In some embodiments, solder pads are arranged on the two connection points on the bottom side of the semiconductor component. This may allow the semiconductor device to be surface mountable, in particular solderable, for example. The solder pads may comprise, for example, a metal stack such as nickel, palladium, gold (NiPdAu) or a comparable solderable metallization.

In some embodiments, at least one side surface of the semiconductor device is substantially perpendicular to the top side of the filler material and the side surface is substantially formed by the filler material. In particular, a side surface of the semiconductor device may be formed substantially only by the filler material and, optionally, to a small extent by the at least partially transparent layer. This has the advantage that in a separation process of several interconnected semiconductor devices only one material and at most two different materials have to be cut.

In some embodiments, the further contact comprises a recess in which the semiconductor component is arranged. In particular, the recess may be in the form of a trough at the lowest point of which the semiconductor component is arranged. At least the inner region of the recess facing the semiconductor component can, for example, be designed as a reflector. For this purpose, at least the further contact may have been galvanized so that a reflector well results in the center of which the semiconductor component is arranged.

In some embodiments, the further contact comprises an aperture through which the through-plating extends. In this case, the further contact and the through-platings are electrically isolated from each other by the filler material.

In some embodiments, the semiconductor component is bonded to the further contact. Accordingly, an adhesive may be formed between the further contact and the semiconductor device.

A method according to the embodiments of invention for manufacturing a semiconductor device, in particular an optoelectronic lighting device, comprises the steps:
depositing an electrically conductive material layer by layer to form a through-plating on an auxiliary carrier;
arranging a semiconductor component at a distance from the through-plating, the component having a first electrical contact surface on an top side of the component and a second electrical contact surface on a bottom side of the component opposite the top side;
introducing a filler material in such a way that the through-plating is enclosed by the filler material as viewed in a circumferential direction and the semiconductor component can be enclosed by the filler material in the circumferential direction, the filler material covering at least a partial region of a side surface of the component connecting the top side and the bottom side of the component, in particular substantially the entire side surface; and
electrically connecting the first electrical contact surface and the through-plating by means of at least one conductive path.

In some embodiments, substantially simultaneously with the step of depositing an electrically conductive material layer-by-layer to form a through-plating, an electrically conductive material for forming a further contact is deposited layer-by-layer on the sub-mount spaced from the through-plating. In this way, a further contact with a layered structure can be produced in addition to the through-plating. In particular, the further contact can be arranged at a distance from the through-plating in such a way that it can be electrically connected to the second electrical contact area of the semiconductor component.

In some embodiments, at least one of the steps of layer-by-layer deposition of an electrically conductive material to form the through-plating and layer-by-layer deposition of an electrically conductive material to form the further contact is performed by means of a 3D printing and/or hardening/sintering process. In particular, both steps are performed by means of a 3D printing and/or hardening/sintering process, in particular with the same. The deposited layers for forming the through-plating and the further contact may have substantially the same thickness. In particular, a layer of the layered structure of the through-plating and a corresponding layer of the further contact may have substantially the same thickness.

In some embodiments, at least one of the steps of layer-by-layer deposition of an electrically conductive material to form the through-plating and layer-by-layer deposition of an electrically conductive material to form the further contact is performed by means of a process in which, per deposited layer, an electrically conductive material is applied, excess material is stripped off, the material is (selectively) fused or fixed/bonded in desired areas, the fused or fixed/bonded material is cured in the desired areas, and uncured material is removed. In particular, both steps are performed by means of such a process, in particular with the same process.

In some embodiments, the step of introducing a filler material occurs after the step of arranging a semiconductor component. In this case, the step of introducing a filler material takes place in particular in the form of a casting process with an electrically insulating material, in particular a ceramic material or a plastic, or a transfer molding process.

In some embodiments, the step of introducing a filler material takes the form of a layer-by-layer deposition of an electrically insulating material to form the filler material. In particular, the layer-by-layer deposition of an electrically insulating material may be performed substantially simultaneously with the step of layer-by-layer deposition of an electrically conductive material to form a through-plating. The deposited layers for forming the through-plating and layers for forming the filler material may have substantially the same thickness. In particular, a layer of the layered structure of the through-plating and a corresponding layer of the filler material may have substantially the same thickness.

In some embodiments, the step of depositing an electrically insulating material layer-by-layer to form the filler material is performed using a process in which, per deposited layer, an electrically insulating material is applied, excess material is stripped, the material is (selectively) fused or fixed/bonded in desired areas, the fused or fixed/bonded material is cured in the desired areas, and uncured material is removed.

In some embodiments, the steps of layer-by-layer deposition of an electrically conductive material to form the through-plating and/or layer-by-layer deposition of an electrically conductive material to form the further contact, as well as the step of layer-by-layer deposition of an electrically insulating material to form the filler material, are performed by means of a process, in particular by means of a process within the same installation. By means of such a system, in particular, superimposed layers can be produced comprising regions that are part of the through-plating, as well as regions that are part of the further contact, if any, and regions that are part of the filler material.

In some embodiments, the step of introducing a filler material creates a cavity in which the semiconductor component is disposed. In particular, the step of introducing a filler material may take the form of depositing an electrically insulating material layer by layer, leaving superimposed regions of the deposited layer exposed so that a cavity is formed.

In some embodiments, the cavity is formed such that a gap is formed between the cavity and the semiconductor component after the semiconductor component is disposed in the cavity. In particular, the semiconductor component can be arranged in the cavity with a nearly precise fit, resulting in a narrow gap between the cavity and the semiconductor component.

In some embodiments, the gap between the semiconductor component and the cavity is filled with the filler material, the filler material is melted or fixed/bonded, and then cured.

In some embodiments, the auxiliary carrier is detached in a further step.

After the auxiliary carrier is detached, for example, at least one of the steps of layer-by-layer deposition of an electrically conductive material to form the through-plating, layer-by-layer deposition of an electrically conductive material to form the further contact, and layer-by-layer deposition of the electrically insulating material to form the filler material, can be continued on a surface of the already deposited layers facing the auxiliary carrier after the auxiliary carrier is detached. Accordingly, the step of detaching the auxiliary carrier may be performed between at least one of the steps of layer-by-layer deposition of an electrically conductive material to form the through-plating, layer-by-layer deposition of an electrically conductive material to form the further contact, and layer-by-layer deposition of the electrically insulating material to form the filler material, and the respective step may be subsequently continued.

In some embodiments, the step of electrically connecting the first electrical contact area and the through-plating by means of the at least one conductive path is performed by means of a 3D printing or hardening/sintering process. In particular, the step of electrically connecting the first electrical contact surface and the through-plating may be performed using the same process as the step of depositing an electrically conductive material layer-by-layer to form the through-plating.

In some embodiments, after, before or during the step of detaching the auxiliary carrier, the semiconductor device is rotated and a first and a second connection point are arranged on the surface of the semiconductor device facing the auxiliary carrier after the auxiliary carrier has been detached, in particular by means of a 3D printing or hardening/sintering process. The first connection point is electrically connected to the at least one conductor track, in particular via the through-plating, and the second connection point is electrically connected to the second electrical contact area, in particular.

In some embodiments, an at least partially transparent layer having light-scattering or light-shaping properties is deposited on an upper surface of the filler material. Alternatively or additionally, the at least partially transparent layer may protect underlying elements or elements of the semiconductor device embedded therein from corrosion.

In some embodiments, the further contact and/or the through-plating contacting is electroplated so that it has, for example, reflective properties. Alternatively or additionally, a reflector may be formed on the further contact and/or the through-plating by means of a 3D printing or a hardening/sintering process.

By the method according to the embodiments of the invention, it is in particular possible to provide a flat semiconductor device which is easy to manufacture due to the proposed method according to embodiments of the invention.

### BRIEF DESCRIPTION OF THE DRAWINGS

In the following, embodiments of the invention are explained in more detail with reference to the accompanying drawings.

FIGS. 1A to 1D show steps of a process according to the proposed principle for manufacturing a semiconductor device;

FIGS. 2A to 2C show a top view and two sectional views of a semiconductor device with some aspects of the proposed principle;

FIGS. 3A to 3C show a top view and two sectional views of another embodiment of a semiconductor device having some aspects of the proposed principle;

FIGS. 4A to 4C show a top view and two sectional views of another embodiment example of a semiconductor device having some aspects of the proposed principle;

FIGS. 5A to 5C show a top view and two sectional views of another embodiment example of a semiconductor device having some aspects of the proposed principle;

FIGS. 6A to 6C show a top view and two sectional views of another embodiment example of a semiconductor device having some aspects of the proposed principle;

FIG. 6D shows a sectional view of another embodiment example of a semiconductor device having some aspects of the proposed principle;

FIGS. 7A to 7C show steps of another embodiment of a method having some aspects of the proposed principle for fabricating a semiconductor device; and

FIGS. 8A to 8C show steps of another embodiment example of a method with some aspects of the proposed principle for manufacturing a semiconductor device.

### DETAILED DESCRIPTION OF ILLUSTRATIVE EMBODIMENTS

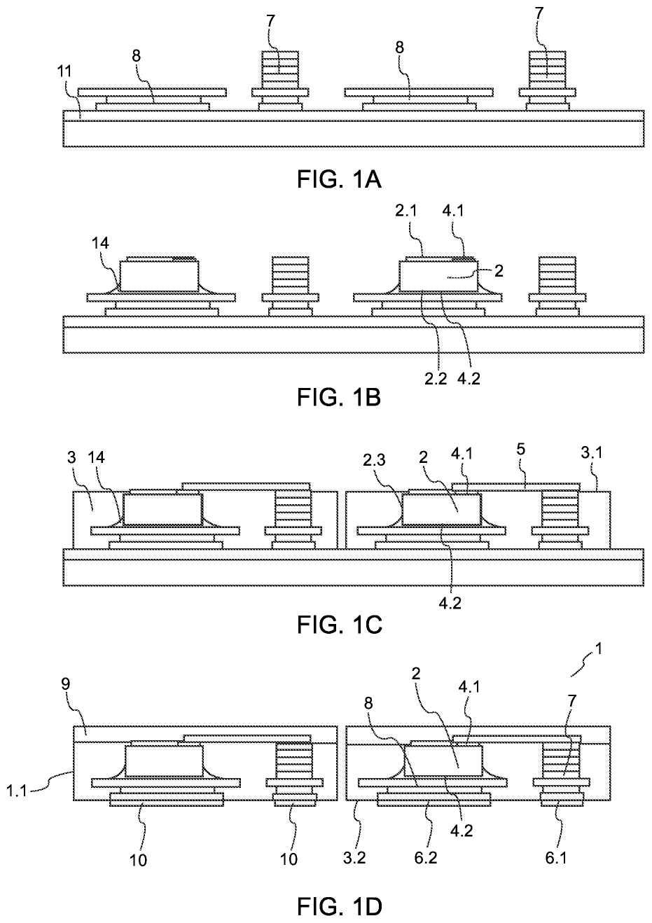

FIGS. 1A to 1D each schematically show steps of a method according to the proposed principle for manufacturing a semiconductor device. In this process, in a first step (FIG. 1A), an electrically conductive material for forming a through-plating contact 7 and for forming a further contact 8 is deposited layer by layer on an auxiliary carrier 11. The auxiliary carrier rests, for example, on a platform.

The illustrated layered structure of the through-plating 7 and the further contact 8 can be produced, for example, by means of a 3D printing or hardening/sintering process. The through-plating 7 and the further contact 8 are arranged spaced apart from one another and can be generated either simultaneously or offset with respect to one another. In particular, however, it is preferred that the through-plating 7 and the further contact 8 are generated in one process step by depositing a first layer of the through-plating 7 on the auxiliary carrier 11 and a first layer of the further contact adjacent to the through-plating on the auxiliary carrier 11. Subsequently, a second layer of the through-plating 7 is deposited over its first layer and a second layer of the further contact 8 is deposited over its first layer. In a corresponding manner, a desired number of layers is deposited on top of each other to form the through-plating and to form the further contact.

The number of layers deposited on top of each other to form the through-plating and to form the further contact can differ. In the present example, for example, three layers are deposited to form the further contact 8 and eight layers are deposited to form the through-plating.

The individual layers of the through-plating 7 and the further contact 8 can have essentially the same thickness, or a layer of the layered structure of the through-plating 7 and a corresponding layer of the further contact 8 can have essentially the same thickness. Depending on the deposition technique used for the layers, a layer of the through-plating 7 and/or the further contact 8 may have a thickness of, for example, 1 to 100 μm.

The cross-sectional area of the individual layers of the through-plating 7 and the further contact 8, viewed in a direction along the layer structure, differs for at least some of the layers from one another in terms of their size and/or shape. As a result, as can be seen from the figure in the illustrated view, a corrugated structure results along the side surfaces of the through-plating 7 and the further contact 8. Furthermore, at least one undercut results in each case for both the through-plating 7 and the further contact 8 in addition to the corrugated structure. In the present example, this arises because the second layer of the through-plating 7 and the further contact 8, viewed from the auxiliary carrier 11 in each case, has a smaller cross-sectional area than the layer above and below it in each case. In each case in the area of the second layer, this results in a constriction of the through-plating 7 and the further contact 8, whereby a filler material introduced subsequently can be fixed relative to the through-plating 7 and the further contact 8.

In a further step, according to FIG. 1B, a semiconductor component 2 having a first electrical contact area 4.1 on an top side 2.1 of the component and a second electrical contact area 4.2 on a bottom side 2.2 of the component opposite the top side is bonded to the further contact 8 by means of an adhesive 14, in particular an electrically conductive adhesive. The semiconductor component 2 is thereby bonded in such a way that the second electrical contact surface 4.2 points in the direction of the further contact 8 and is electrically connected to it.

The semiconductor component 2 can, for example, be an optoelectronic semiconductor chip in the form of a detector, a volume emitter or in the form of a surface emitter. A main radiation surface or detection surface of the semiconductor component 2 can preferably be formed parallel to the top side 2.1 of the semiconductor component 2.

In FIG. 1C, an electrically insulating filler material is now introduced in a further step to enclose the through-plating 7, the further contact 8 and the semiconductor component 2 as viewed in a circumferential direction. The filler material is introduced, for example, in the form of a casting process and serves in particular to electrically insulate the through-plating and the further contact from one another. Furthermore, the filler material serves to provide mechanical stability of the semiconductor device 1. For this purpose, the filler material has SiO2 spheres and a plastic.

The filler material extends into the undercut of the through-plating 7 and the further contact 8, so that the filler material 3 is fixed with respect to the through-plating 7 and the further contact 8. After the filler material has cured, it can no longer be removed from the through-plating 7 and the further contact 8 without causing damage due to the undercuts.

The top side 2.1 of the semiconductor component 2 is not covered by the filler material, but an top side 3.1 of the filler material 3 is substantially flush with the top side of the semiconductor component 2 or is adjacent thereto. A conductive track 5 is applied to the top side 3.1 of the filler material 3 and electrically connected to the first electrical contact area 4.1 and the through-plating 7. In this embodiment, the conductive track 5 is also generated by means of a 3D printing or hardening/sintering process, in particular the conductive track 5 is generated by the same process as the through-plating 7 and the further contact 8.

By means of the conductor track 5 and the through-plating 7 through the filler material 3, an electrical connection is provided between the first electrical contact area 4.1 and a first connection point 6.1 adjacent to the bottom side of the filler material 3.2. By means of the through-plating 7, the top-side contact of the semiconductor component 2 can thus be guided to the bottom side of the semiconductor component, so that the semiconductor device 1 can be mounted via the first connection point 6.1 and a second connection point 6.2 adjacent thereto in a manner similar to a flip chip.

FIG. 1D shows an embodiment example of a semiconductor device 1 according to the invention. To produce the semiconductor component, the auxiliary carrier 11 of FIGS. 1A to 1C was removed and both the top side 3.1 and the bottom side 3.2 of the filler material were further processed. An at least partially transparent layer 9 having light-scattering or light-shaping properties is arranged on the upper surface of the filler material. Alternatively or additionally, the at least partially transparent layer 9 is formed in such a way that underlying elements or elements of the semiconductor device 1 embedded therein are protected against corrosion. Furthermore, solder pads are arranged on the first and second connection points 6.1, 6.2, which are arranged adjacent to the bottom side 3.2 of the filler material, whereby the semiconductor component becomes, for example, surface-mountable, in particular solderable.

A side surface 1.1 of the semiconductor device 1 extends substantially perpendicular to the top side 3.1 of the filler material, and the side surface 1.1 is substantially formed by the filler material 3. In the present case, the side surface 1.1 of the semiconductor component is largely formed only by the filler material 3 and to a small extent by the at least partially transparent layer 9. This has the advantage that in a separation process of several interconnected semiconductor components only one material and at most two different materials have to be cut through.

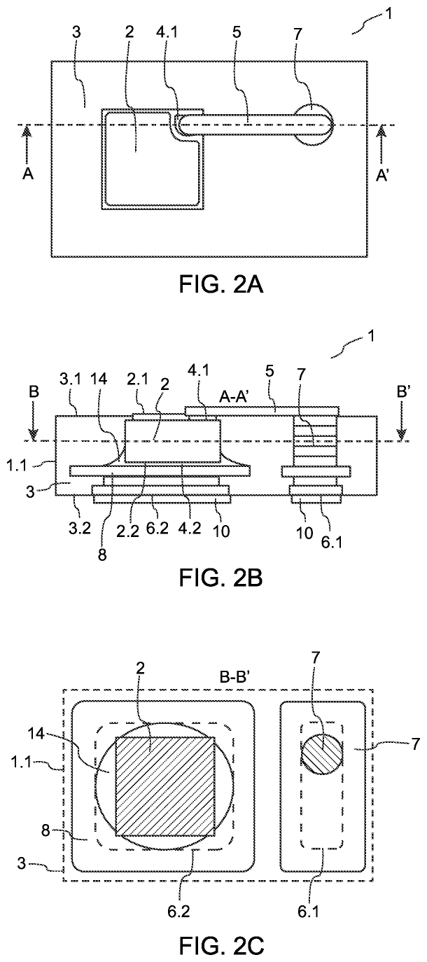

FIGS. 2A to 2C show a top view and two sectional views of a further embodiment of a semiconductor device 1 according to the invention. FIG. 2A shows the top view of the semiconductor device 1. The semiconductor device 1 has a rectangular cross-sectional area with an edge length of, for example, 1 to 5 mm. The semiconductor device includes the filler material 3, the semiconductor component 2, the through-plating 7, and the conductor track 5 electrically connecting the through-plating 7 and the first electrical contact area 4.1 of the semiconductor component 2 on the top side 2.1 of the semiconductor component 2.

As shown in the figure, the through-plating comprises a circular cross-sectional area and is arranged adjacent to that of the semiconductor component 2.

FIG. 2B shows a sectional view through the semiconductor device 1 of FIG. 2A along line A-A′. The sectional view shows substantially the semiconductor device 1 of FIG. 1D without, however, the at least partially transparent layer 9.

FIG. 2C shows a sectional view through the semiconductor device 1 of FIG. 2B along the line B-B′ in which the filler material 3 is hidden or only the outer contour of the filler material 3 is indicated by means of a dashed line. The cross-sectional area of the semiconductor component 2 and the through-plating 7 in the sectional plane is shown hatched, and the two connection points (6.1, 6.2) on the bottom side of the semiconductor component are again indicated by dashed lines.

The through-plating 7 has a rectangular cross-sectional area in its lower region, which has substantially the same length as the cross-sectional area of the further contact 8. From the layer of the through-plating 7 corresponding to the layer of the further contact 8 on which the semiconductor component 2 is arranged, the through-plating extends upward in the form of a layered column with a circular cross-sectional area. The circular cross-sectional area of the through-plating 7 is thereby significantly smaller in relation to the rectangular cross-sectional area of the underlying layer.

At least the uppermost layer of the further contact 8 also has a rectangular, in particular square, cross-sectional area which is larger than the cross-sectional area of the semiconductor component 2. This can, for example, facilitate the arrangement of the semiconductor component 2 on the further contact 8, and electrical contacting is ensured between the second electrical contact surface 4.2 on the bottom side 2.2 of the semiconductor component 2 and the further contact 8.

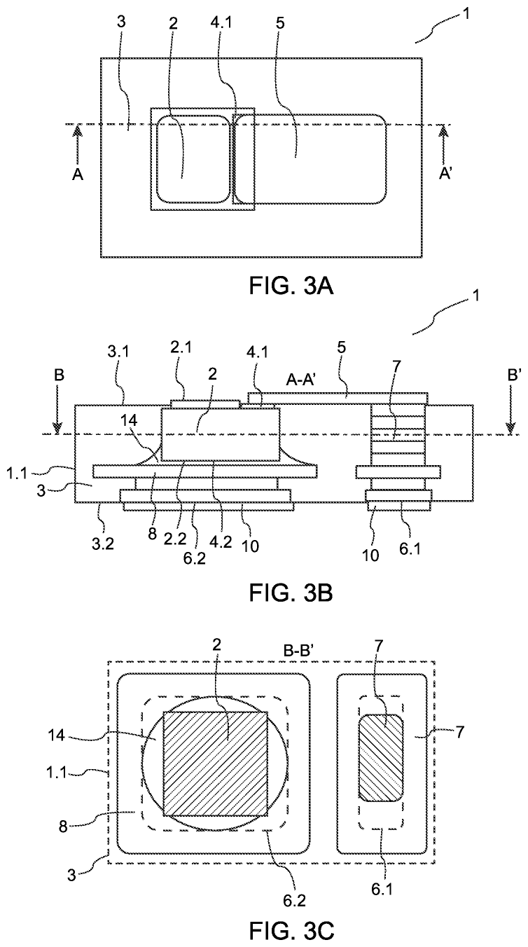

FIGS. 3A to 3C show a top view and two sectional views of a further embodiment of a semiconductor device 1 according to the invention. Here, FIG. 3A shows the top view of the semiconductor device 1. In contrast to the semiconductor component in FIGS. 2A to 2C, the semiconductor device 1 has a wider conductor track 5 and a through-plating 7 with a larger and rectangular cross-sectional area in the upper region of the semiconductor device 1. Accordingly, the first electrical contact area 4.1 is also formed to be larger compared to the first electrical contact area shown in FIGS. 2A to 2C.

The widening of the conductive path and the increase in the cross-sectional area of the through-plating 7 in the upper region of the semiconductor device 1 may serve, for example, to allow the heat generated at the upper surface of the semiconductor device to be dissipated more effectively.

FIGS. 3B and 3C show the corresponding sectional views of the semiconductor device 1 along lines A-A′ and B-B′, respectively. It should be mentioned that in FIG. 3C, the cross-sectional area of the through-plating 7 shown hatched in the sectional plane is enlarged and changed in shape compared to FIG. 2C.

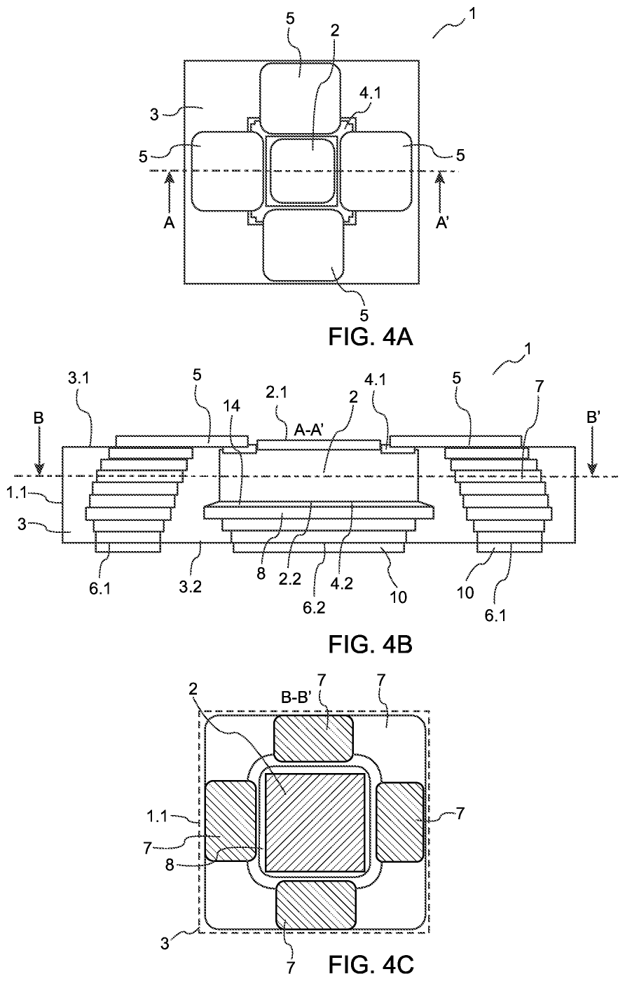

FIGS. 4A to 4C show a top view and two sectional views of a further embodiment of a semiconductor device 1 according to the invention. Here, FIG. 4A shows the top view of the semiconductor device 1. In contrast to the semiconductor component in FIGS. 3A to 3C, the semiconductor device 1 has four conductor tracks 5 which electrically connect the through-plating 7 to the first electrical contact area 4.1.

In this case, the four conductor tracks 5 are arranged point-symmetrically with respect to the center of the semiconductor component 2 or axially symmetrically with respect to the symmetry axes of the cross-sectional area of the semiconductor component 2 on the top side 3.1 of the filler material at a uniform distance from one another. Accordingly, the first electrical contact area 4.1 is also larger compared to the first electrical contact area shown in FIG. 3A and is formed in the shape of a frame on the upper surface 2.1 of the semiconductor component 2, so that the four conductive paths 5 can be electrically connected to each other with the first electrical contact area 4.1.

The layers of the through-plating 7 have a cross-sectional area in the form of a square frame in the lower portion of the through-plating. In other words, the layers of the through-plating 7 have, in the lower region thereof, a cross-sectional area in the form of a square which comprises a square recess in the center thereof. However, the shape of the cross-sectional area is not limited to a square frame, but can also be in the form of a ring or a frame with a differently shaped base and recess.

Within the recess, in particular in the center of the recess, the further contact 8 and the semiconductor component 2 arranged thereon are arranged. The recess is larger than the cross-sectional area of the layers of the further contact 8 or larger than the cross-sectional area of the semiconductor component 2, so that a gap is formed between the layers of the through-plating 7 and the layers of the further contact 8, which is filled with the filler material and the through-plating 7 and the further contact 8 are thus electrically insulated from each other (see FIGS. 4B and 4C).

Starting from the layer of the through-plating 7 corresponding to the layer of the further contact 8 on which the semiconductor component 2 is arranged, the through-plating extends upward in the form of four pillars having a rectangular cross-sectional area (see hatched blocks 7 in FIG. 4C). The four pillars are arranged corresponding to the four conductive paths 5 point-symmetrically with respect to the center of the semiconductor component 2, or axially symmetrically with respect to the symmetry axes of the cross-sectional area of the semiconductor component 2, and are uniformly spaced apart from each other around the semiconductor component 2.

The arrangement of four conductive paths 5 and four pillars of through-plating 7 in the upper portion of the semiconductor device 1 may serve, for example, to help dissipate heat generated at the top side of the semiconductor device.

In contrast to the embodiment shown in FIGS. 3A to 3C, the through-plating 7 and the further contact 8 in FIG. 4B do not have an undercut by themselves, but an undercut results from the combination of the through-plating 7, the further contact 8 and the wiring track 5, so that the filler material is fixed with respect to said elements. However, it is also possible that the through-plating 7 and/or the further contact 8 are formed in such a way that they have an undercut by themselves.

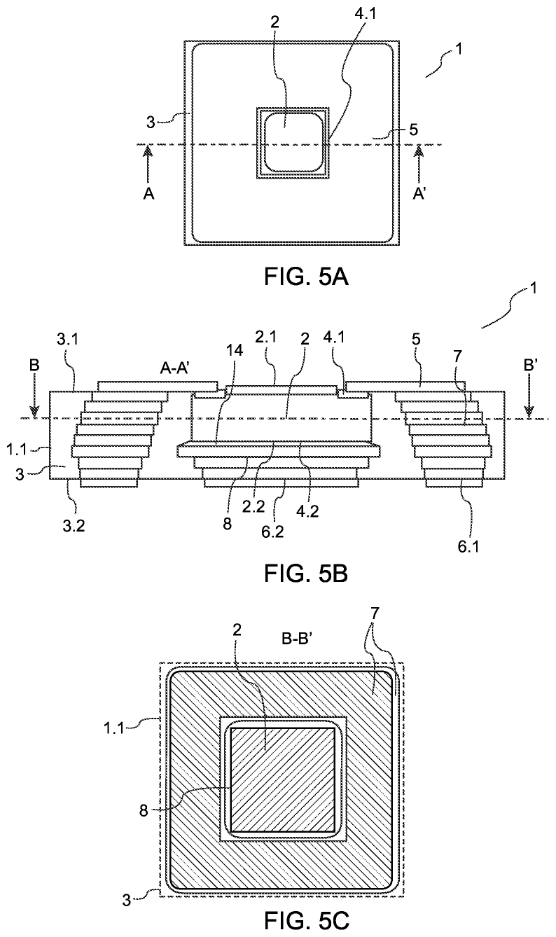

FIGS. 5A to 5C show a top view and two sectional views of a further embodiment of a semiconductor device 1 according to the invention. In this context, FIG. 5A shows the top view of the semiconductor device 1. In contrast to the semiconductor component in FIGS. 4A to 4C, the semiconductor device 1 has a frame-shaped conductor track 5 which electrically connects the through-plating 7 to the first electrical contact area 4.1.

The conductive track 5 covers substantially the entire top side 3.1 of the filler material, and substantially only the top side 2.1 of the semiconductor component 2 is not covered by the conductive track 5. The first electrical contact area 4.1 is formed in the shape of a frame on the top side 2.1 of the semiconductor component 2, so that the conductor track 5 can be electrically connected to the first electrical contact area 4.1 over the entire circumferential direction of the frame.

The layers of the through-plating 7 have a cross-sectional area in the form of a square frame throughout the entire layer structure. In other words, the layers of the through-plating 7 have a cross-sectional area in the shape of a square, which has a square recess in its center. However, the shape of the cross-sectional area is not limited to a square frame, but may also be in the form of a ring or a frame having a differently shaped base and recess.

Within the recess, in particular in the center of the recess, the further contact 8 and the semiconductor component 2 arranged thereon are arranged. The recess is larger than the cross-sectional area of the layers of the further contact 8 or larger than the cross-sectional area of the semiconductor component 2, so that a gap is formed between the layers of the through-plating 7 and the layers of the further contact 8, which gap is filled with the filler material and the through-plating 7 and the further contact 8 are thus electrically insulated from each other (see FIGS. 5B and SC).

By forming a through-plating that comprises a cross-sectional area in the form of a square frame throughout its layered structure, heat generated at the top of the semiconductor device is better dissipated. In addition to this, the frame-shaped through-plating can act as a reflector so that-in the case of a light emitter as a semiconductor component 2—light is emitted from the semiconductor device 1 substantially only in the region of the top side of the semiconductor component 2.

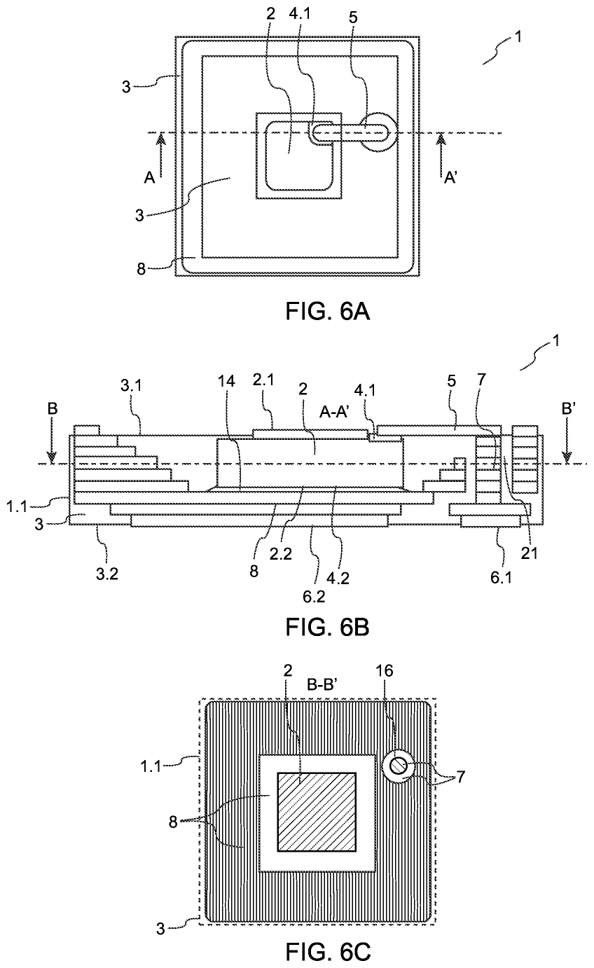

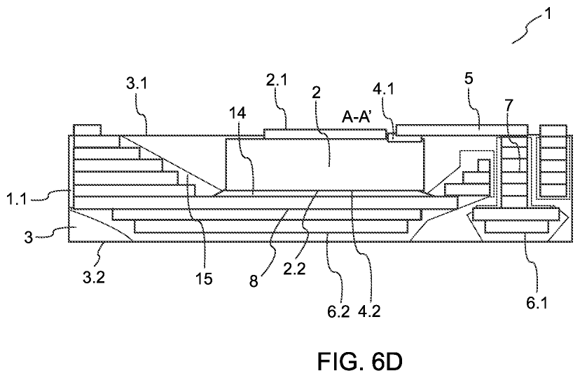

FIGS. 6A to 6C show a top view and two sectional views of a further embodiment of a semiconductor device 1 according to the invention. FIG. 6A shows the top view of the semiconductor device 1. In contrast to the preceding semiconductor component, the semiconductor device 1 has a further contact, which is formed in the form of a recess.

The semiconductor component 2 is arranged in the recess, or at its deepest point in the center of the recess. The recess is formed in the present case by the fact that at least some of the layers of the further contact 8, have a cross-sectional area in the form of a square frame, in particular all the layers which lie above the layer on which the semiconductor component 2 is arranged. In other words, the layers of the further contact 8 that lie above the layer on which the semiconductor component 2 is disposed have a cross-sectional area in the form of a square having a square recess in the center thereof. Here, the recess has a conical shape formed by the recesses of the in the layers of the further contact becoming gradually larger toward the top of the filler material 3 (see FIG. 6B).

However, the shape of the cross-sectional area is not limited to a square frame, but can also be in the form of a ring or a frame with a differently shaped base and recess.

A through-plating 21 is formed by the further contact, through which the through-plating 7 extends. The further contact 8 and the through-plating 7 are electrically insulated from each other by the filler material. In the present case, the aperture 21 has a circular cross section (see FIG. 6C) and the through-plating 7 is designed in accordance with the through-plating 7 as described in FIG. 2C.

By forming the further contact 8 in such a way that it forms a recess, at the deepest point of which the semiconductor component is arranged, the further contact 8 acts, for example, as a reflector, so that-in the case of a light emitter as semiconductor component 2—light is emitted from the semiconductor device 1 essentially only in the region of the top side of the semiconductor device 1 or the top side 3.1 of the filler material and the top side 2.1 of the semiconductor component.

In order to improve the reflector properties, at least the further contact, in particular the region of the recess which is extended in the direction of the semiconductor component 2, can be electroplated so that a reflector well is formed, in the center of which the semiconductor component is arranged.

FIG. 6D shows an example of such an embodiment, in which in particular the region of the recess which extends in the direction of the semiconductor component 2 is formed as a reflector by means of a coating 15. In the figure, all surface areas of the further contact 8 and of the through-plating 7 are galvanized, so that the coating 15 extends over all surface areas of the further contact 8 and of the through-plating 7.

The coating can be applied, for example, by an electroplating process, a deposition process or by 3D printing.

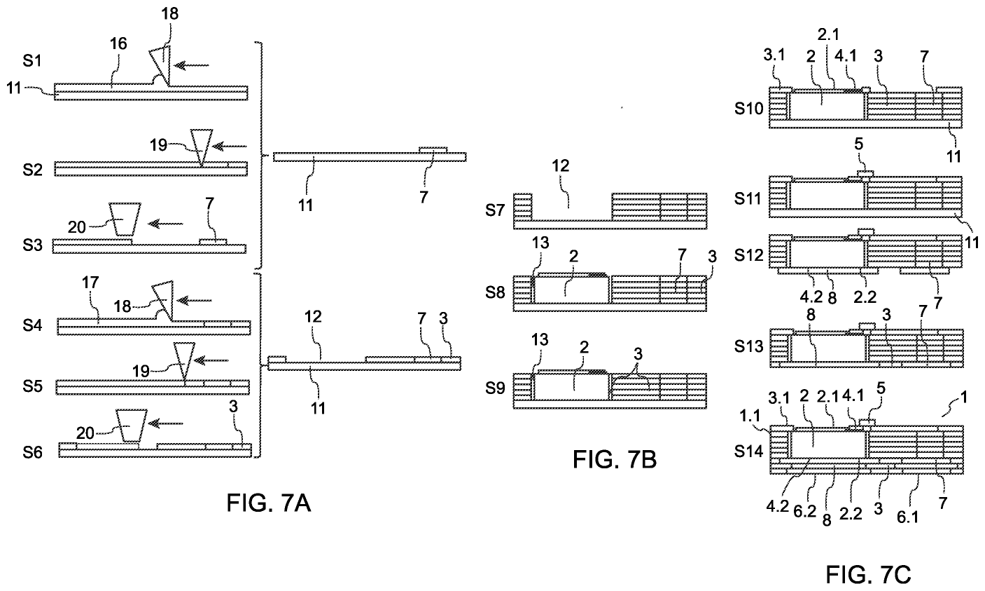

FIGS. 7A to 7C show steps of an embodiment example of a method according to the invention for manufacturing a semiconductor component. In a first step S1, an electrically conductive material 16, in particular powder, is thereby applied to an auxiliary carrier 11 according to FIG. 7A and is scraped off with a doctor blade 18, so that a layer of the electrically conductive material 16 is obtained which has a desired thickness. In a further step S2, the electrically conductive material 16 is then melted by means of a laser 19 or a binder is applied by means of an inkjet nozzle in a previously defined area in order to fix the electrically conductive material 16. When the melted or fixed area has cured, a suction cup 20 is used to remove the loose material in a further step S3. The result from the three steps S1-S3 is shown on the right of the three figures, after which a first layer of the through-plating 7 has been formed on the submount by means of the three steps.

Following this, in a further step S4, an electrically insulating material 17, in particular powder, is applied to the submount ii and wiped off with a squeegee 18. The electrically insulating material 17 is stripped off in such a way that a layer of the electrically insulating material 17 is obtained which has essentially the same thickness as the layer of the through-plating 7 already arranged on the auxiliary carrier. In a further step S5, the electrically insulating material 17 is then melted by means of a laser 19 or a binder is applied by means of an inkjet nozzle in a previously defined area in order to fix the electrically insulating material 17. When the melted or fixed area has cured, a suction component 20 is used to remove the loose material in a further step S6.

The result from the three steps S4-S6 is shown on the right of the three figures, according to which, by means of the three steps, a first layer of the filler material has been formed on the submount in addition to the first layer of the through-plating 7, the filler material having a cavity 12.

Steps S1-S6 can be repeated in a further step S7 on the first layer of the through-plating and the first layer of the filler material 3, so that after repeating the steps a number of times the layered structure shown in FIG. 7B above is obtained. The layered structure in the present example has five layers which together form the filler material 3 with the cavity 12 and the through-plating 7.

In a further step S8, a semiconductor component 2 is arranged in the cavity, and in a step S9, a gap 13 formed between the outer wall of the cavity and the semiconductor component 2 is filled with the electrically insulating material 17. The electrically insulating material 17 in the gap 13 is melted by means of a laser or a binder is applied by means of an inkjet nozzle to fix the electrically insulating material 17. Subsequently, the melted or fixed material is cured. By this process, the semiconductor component 2 is fixed in the cavity.

In a step S10 (see FIG. 7C), another layer of filler material is applied to the top layer of the layer stack, in particular using a process as shown in steps S4-S6, and then, in a step Sn, a conductor track 5 is applied, in particular using a process as shown in steps S1-S3.

Subsequently, in a step S12, the auxiliary carrier 11 is detached and removed and the already generated layer stack is preferably turned over. On the side of the layer stack facing the auxiliary carrier 11, after the auxiliary carrier 11 has been removed, a further layer of the through-plating 7 and a first layer of a further contact 8 are then applied, in particular using a process as shown in steps S1-S3.

In a step S13, a further layer of the filler material 3 is subsequently applied thereto, in particular using a method as shown in steps S4-S6.

Steps S12 and S13 can be repeated as often as desired in a step S14 until a desired height of the layer stack is obtained. In the present case, after removing the auxiliary carrier 11, three more layers are deposited on the bottom side of the semiconductor component 2, resulting in the layer stack shown in FIG. 7C below or the semiconductor device 1 shown in FIG. 7C below.

The through-plating contact 7 and the further contact 8 each have a connection point (6.1, 6.2) and an undercut on the bottom side thereof.

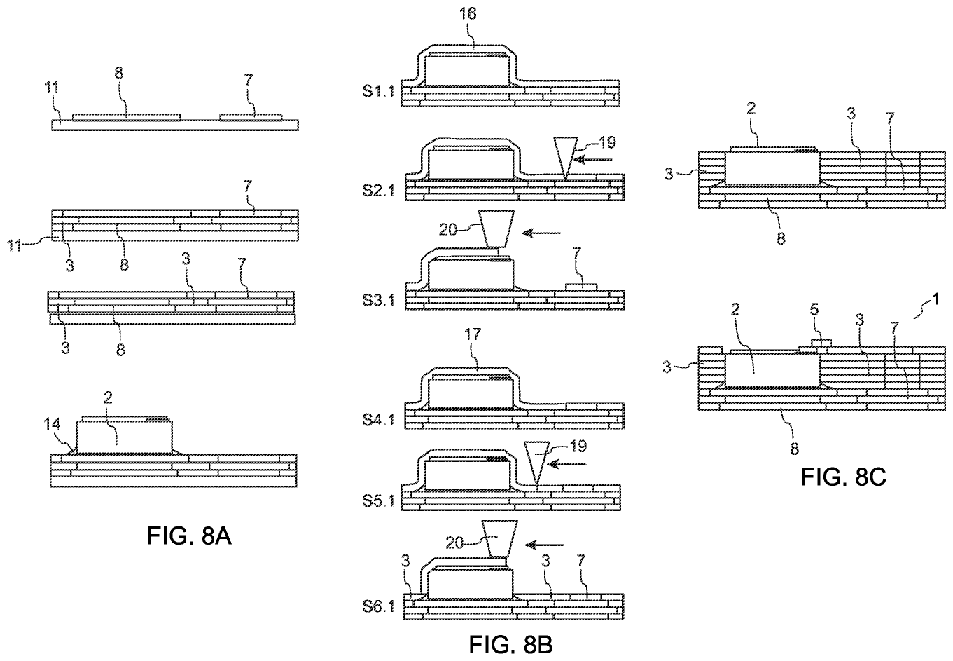

FIGS. 8A to 8C show steps of a further embodiment of a method according to the invention for producing a semiconductor device 1. According to FIG. 8A, layers of a through-plating 7, a further contact 8 and a filler material 3 are deposited step by step on an auxiliary carrier. The layers of the through-plating 7 and the further contact 8 can be deposited by a method comprising the steps S1-S3 of the method shown in FIG. 7A. The layers of the filler material, on the other hand, can be applied by a method comprising steps S4-S6 of the method shown in FIG. 7A.

However, compared to the method illustrated in FIGS. 7A and 7B, no cavity is created in the filler material 3, but layers of the further contact material 8 are applied to the auxiliary carrier 11 in order to fix the semiconductor component 2 directly to the further contact material, in particular to glue it (see lower figure of FIG. 8A).

Once the semiconductor component 2 is deposited on the further contact 8, it is not further possible to apply further layers of the filler material 3 and the through-plating 7 by means of the steps S1-S6 shown in FIG. 7A, since in particular the step of stripping (S2 and S4) is not further possible due to the topography of the layer stack.

FIG. 8B shows alternative steps S1.1 to S6.1 for this purpose. In a step S1.1, an electrically conductive material 16, in particular powder, is applied to the semiconductor component 2 and the uppermost layer of the already generated layer stack. Instead of stripping, however, a uniform distribution for generating a uniform layer of the electrically conductive material 16 is carried out, for example, by means of weighing the required material and jogging the applied weighed material. Alternatively, a uniform layer of the electrically conductive material 16 may be applied, for example, by means of a multi-stage spraying process, for which purpose the electrically conductive material 16 may be mixed with, for example, a gas and/or a volatile liquid. In a further alternative, the electrically conductive material 16 can be applied to previously defined areas, for example, by means of a screening process and a suitably formed mask arranged above the stack of layers.

In a further step S2.1, the electrically conductive material 16 is then melted by means of a laser 19 or a binder is applied by means of an inkjet nozzle in a previously defined area in order to fix the electrically conductive material 16. When the melted or fixed area has hardened, the loose material is removed by means of a suction cup 20 in a further step S3.1.

Following this, in a further step S4.1, an electrically insulating material 17, in particular powder, is applied in accordance with step S1.i. In a further step S5.1, the electrically insulating material 17 is then melted by means of a laser 19 or a binder is applied by means of an inkjet nozzle in a previously defined area in order to fix the electrically insulating material 17. When the melted or fixed area is cured, a suction cup 20 is used to remove the loose material in a further step S6.1.

With the steps shown in FIG. 8B, it is possible to apply a 3D printing and/or hardening/sintering process also for components with an existing surface topography, or to provide the semiconductor component according to the invention.

Steps S1.1 to S6.1 can be repeated as many times as desired to provide the layer stack shown in the upper image in FIG. 8C. A conductive path 5 is then applied to the layer stack to electrically connect the through-plating 7 and the first electrical contact area 4.1. Both steps S1 to S6 shown in FIG. 7A but also steps S1.1 to S6.1 shown in FIG. 8B can be used for this purpose.

The auxiliary carrier, which is no longer shown in FIGS. 8B and 8C, can be removed at any time as soon as at least a complete first layer of the layer stack has been generated. Accordingly, the process illustrated in FIGS. 8A to 8C results in the semiconductor device 1 shown in the lower figure in FIG. 8C.

1-24. (canceled)

25. A semiconductor device comprising:
a semiconductor component having a first electrical contact surface on a top side of the component and a second electrical contact surface on a bottom side of the component opposite the top side;
a filler material enclosing the semiconductor component as seen in a circumferential direction, the filler material covering at least a partial region of a side surface of the component connecting the top side and the bottom side;
at least one conductor track arranged on a top side of the filler material, the at least one conductor track being electrically connected to the first electrical contact surface; and
a first connection point and a second connection point arranged adjacent to a bottom side of the filler material opposite the top side of the filler material, the first connection point being electrically connected to the at least one conductor track via a through-plating through the filler material and the second connection point being electrically connected to the second electrical contact surface,
wherein the through-plating has a layered structure and at least one undercut in order to fix the filler material.

26. The semiconductor device according to claim 25, further comprising a further contact formed through the filler material and electrically connecting the second connection point to the second electrical contact surface.

27. The semiconductor device according to claim 26, wherein the further contact has a layered structure and/or has at least one undercut in order to fix the filler material.

28. The semiconductor device according to claim 27, wherein a layer of the layered structure of the through-plating and a corresponding layer of the further contact have substantially the same thickness.

29. The semiconductor device according to claim 26, wherein the further contact substantially comprises a recess in which the semiconductor component is arranged.

30. The semiconductor device according to claim 29, wherein the further contact comprises an opening through which the through-plating extends, and wherein the further contact and the through-plating are electrically insulated from one another by the filler material.

31. The semiconductor device according to claim 29, wherein at least an inner region of the recess facing the semiconductor component is a reflector.

32. The semiconductor device according to claim 25, further comprising an at least partially transparent layer arranged on the top side of the filler material, wherein the at least partially transparent layer has light-scattering or light-shaping properties, or, wherein the at least partially transparent layer protects underlying elements or elements of the semiconductor component embedded therein against corrosion.

33. The semiconductor device according to claim 25, further comprising solder pads arranged on the connection points.

34. The semiconductor device according to claim 25, wherein at least one side surface of the semiconductor component extends substantially perpendicular to the top side of the filler material and is substantially formed by the filler material.

35. The semiconductor device according to claim 25, wherein at least one of the at least one conductor track, the through-plating and the further contact comprises printed and/or sintered copper or silver layers.

36. The semiconductor device according to claim 25, wherein the semiconductor component is bonded to the further contact.

37. A method for manufacturing a semiconductor device, the method comprising:
depositing an electrically conductive material layer by layer to form a through-plating on an auxiliary carrier;
arranging a semiconductor component at a distance from the through-plating, the component having a first electrical contact surface on a top side of the component and a second electrical contact surface on a bottom side of the component opposite the top side;
introducing a filler material in such a way that the through-plating is enclosed by the filler material, as seen from a circumferential direction, and in such a way that the semiconductor component is enclosed by the filler material in the circumferential direction,
wherein the filler material covers at least a partial region of a side surface of the component which connects the top side and the bottom side of the component; and
electrically connecting the first electrical contact surface and the through-plating by at least one conductor track.

38. The method according to claim 37, wherein depositing the electrically conductive material layer by layer to form the through-plating and depositing an electrically conductive material to form a further contact layer by layer on the auxiliary carrier at a distance from the through-plating is performed substantially simultaneously.

39. The method according to claim 37, wherein at least one of depositing the electrically conductive material layer-by-layer to form the through-plating or depositing an electrically conductive material layer-by-layer to form a further contact comprises 3D printing and/or hardening/sintering.

40. The method according to claim 37, wherein at least one of depositing the electrically conductive material layer by layer to form the through-plating or depositing an electrically conductive material layer by layer to form a further contact comprises:
depositing the electrically conductive material;
stripping off an excess material;
melting or fixing the material in desired areas;
curing the material in the desired areas; and
removing an uncured material.

41. The method according to claim 37, wherein introducing the filler material is conducted after arranging the semiconductor device, and wherein introducing the filler material comprises a casting process or a transfer molding process.

42. The method according to claim 37, wherein introducing the filler material by a layer-by-layer deposition of the electrically insulating material to form the filler material is conducted substantially simultaneously with a layer-by-layer deposition of the electrically conductive material to form the through-plating, and wherein deposited layers to form the through-plating and layers to form the filler material have substantially the same thickness.

43. The method according to claim 37, wherein introducing the filler material comprises creating a cavity in which the semiconductor device is placed.

44. The method according to claim 43, further comprising filling a gap between the semiconductor device and the cavity with the filler material.

45. The method according to claim 37, further comprising detaching the auxiliary carrier.

46. The method according to claim 45, wherein electrically connecting a first electrical contact area and the through-plating by the at least one conductor track comprises 3D printing or hardening/sintering.

47. The method according to claim 45,
wherein after, before or during detaching the auxiliary carrier, the semiconductor component is rotated, and a first connection point and a second connection point are arranged on the surface of the semiconductor component facing the auxiliary carrier after the auxiliary carrier has been detached, and
wherein the first connection point is electrically connected to the at least one conductor track via the through-plating and the second connection point is electrically connected to the second electrical contact surface.

48. The method according to claim 37, further comprising depositing an at least partially transparent layer on a top side of the filler material, wherein the at least partially transparent layer has light-scattering or light-shaping properties, or wherein the at least partially transparent layer protects underlying elements or elements of the semiconductor component embedded therein from corrosion.
